(19) United States
(12) Patent Application Publication
(10) Pub. No.: US 2005/0180197 A1
(43) Pub. Date: Aug. 18, 2005

(54) Output device for static random access memory

(75) Inventor: Chao-Sheng Huang, Taipei (TW)

Correspondence Address: BACON & THOMAS, PLLC, 625 SLATERS LANE, FOURTH FLOOR, ALEXANDRIA, VA, 22314, US

(73) Assignee: VIA Technologies, Inc., Taipei (TW)

(21) Appl. No.: 10/978,350

(22) Filed: Nov. 2, 2004

(30) Foreign Application Priority Data
Feb. 13, 2004 (TW) 093103484

(51) Int. Cl. G11C 11/00

(52) U.S. Cl. 365/154

(57) ABSTRACT

An output device for static random access memory (SRAM) is disclosed, which has a precharger, a charge and discharge path circuit, a voltage hold circuit and an output inverter. The precharger is connected to a common output node for a plurality of memory cells. The precharger has a precharge node and at least one transmitting gate coupled to the common output node and the precharge node. When one of the memory cells is to be read, the precharge node is precharged to a high potential. A gate of the transmitting gate is connected to a high potential so that a potential of the common output node is charged only to a potential of (Vdd-V_{T}) when precharging. Thus, the common output node's potential can be pulled more faster down to a low potential, thereby increasing read speed on memory cells.

### BACKGROUND OF THE INVENTION

1. Field of the Invention

The present invention relates to the technical field of static random access memory (SRAM) and, more particularly, to an output device for static random access memory.

2. Description of Related Art

FIG. 1 is a schematic diagram of a typical dual-port SRAM and the output device thereof, wherein, for illustrative purpose, only one memory cell 100 is described, while others are schematically represented by dotted lines. As shown, the memory cell 100 consists of a plurality of metal oxide semiconductor (MOS) transistors, and its output end is provided with an N-type metal oxide semiconductor (NMOS) transistor MR. The transistor MR has a drain connected to a node E of an output device 120, a gate connected to a control signal RWL (read word line) in order to control whether or not data of the memory cell 100 is sent to the node E. The output device 120 consists of P-type metal oxide semiconductor (PMOS) transistors 101, 103, 105 and 107 and NMOS transistors 102, 104 and 106.

FIG. 2 shows a timing diagram of the output device 120. As shown in FIG. 2, when data of the memory cell is to be read, the node E of the output device 120 maintains at high potential for a pre-charging process. Accordingly, in T1 interval, control signals PRE and RWL are at low potential respectively, the transistor MR is in off state, and the transistor 101 is turned on such that a source of the transistor 101 connects to a voltage Vdd in order to precharge the node E and further maintain the node E at high potential. Next, in T2 interval, the potential of the control signal PRE changes from low to high, which represents that the pre-charge on the node E is complete. Then, in the T3 interval, the potential of the control signal RWL changes from low to high, which turns on the NMOS transistor MR. It represents that data of the memory cell 100 is sending to the output device 120. Next, after the T3 interval, when data of the memory cell 100 is in high potential, a node F of the memory cell 100 is in low potential so that the transistor MP of the memory cell 100 is in off state. At this point, the node E maintains at high potential due to precharging. Therefore, the NMOS transistor 102 is turned on such that it maintains a node G at low potential to further output a high potential (the same as data of the memory cell 100) at the output terminal OUT through an inverter 122 consisting of MOS transistors 106 and 107. On the other hand, when data of the memory cell 100 is in a low potential, the node F of the memory cell 100 is in a high potential, the transistor MP of the memory cell 100 is turned on. At this point, a source of the transistor MP has a ground potential ‘gnd’ and the node E changes from high potential to low potential. Meanwhile, the PMOS transistor 103 is turned on to maintain the node G at high potential, and thus the node OUT outputs a low potential (the same as data of the memory cell 100 sent) through the inverter 122 consisting of MOS transistors 106 and 107. However, as cited, since the node E connects to a plurality of memory cells, the load of the node E is heavier (indicated by a capacitor 108). When the node E changes from high potential to low potential, it needs more time to pull the potential down, resulting in that heavy load on node E (many memory cells). Besides, the NMOS transistor 102 is not completely turned off so that a time point of pulling the node G to the high potential by the transistor 103 is weakened and thus the node G maintains at a low potential when receiving the source potential of the MOS transistor 102, which causes the PMOS transistor 105 turned on. Therefore, a voltage Vdd is provided to the node E through a source of the PMOS transistor 105, so that the node E cannot change quickly from high potential to low and it wastes a long time. Accordingly, a long switching time is necessary when data of the memory cell cell 100 is in a low potential.

Further, when a previous memory cell is read as low potential, the node E is at low potential. Since the PMOS transistor 103 is turned on when the node E is at low potential, its source voltage is sent to the node G in order to turn on the NMOS transistor 104. Therefore, a voltage ‘gnd’ is applied to the node E through a source of the transistor 104. When a precharge is performed in T1 interval, the node E is charged by the source voltage Vdd of the transistor 101 to high potential. The transistors 101 and 104 function as shown in FIG. 3. The transistor 104 maintains the node E at low potential, and conversely the transistor 101 maintains the node E at high potential. Accordingly, a very small die size is applied to the transistor 104 in design, much smaller than that to the transistor 101, thereby obtaining a higher driving capability to achieve the precharge to the node E.

However, by contrast, the very small die size transistor 104 has poorer driving capability. This may affect transmitting data of the memory cell 100 with low potential because when the node G changes to high potential after a certain time waste and thus the NMOS transistor 104 is turned on to provide the node E with its source voltage ‘gnd’, the effect of speeding the node E down to a low voltage is relatively reduced due to the cited poorer driving capability. Thus, read speed of the memory cell cannot be increased.

Therefore, it is desirable to provide an improved output device for SRAM to mitigate and/or obviate the aforementioned problems.

### SUMMARY OF THE INVENTION

The object of the present invention is to provide an output device for static random access memory (SRAM), which can speed up potential transition on nodes of the output device and further increase read speed of the memory.

To achieve the object, the output device of the present invention includes a precharger, a charge and discharge path circuit, a voltage hold circuit and an output inverter. The precharger connected to a common output node for a plurality of memory cells has a precharge node and at least one transmitting gate coupled between the common output node and the precharge node. When one of the memory cells is to be read, the precharge node is precharged to a high potential. The charge and discharge path circuit connects to the precharge node and controls an output voltage on its output node in accordance with a potential of the precharge node. The voltage hold circuit connects to both the output node of the charge and discharge path circuit and the precharge node of the precharger and controls its output voltage in accordance with the output voltage of the charge and discharge path circuit. The output inverter generates an inverse voltage to output in accordance with the output voltage of the voltage hold circuit.

Other objects, advantages, and novel features of the invention will become more apparent from the following detailed description when taken in conjunction with the accompanying drawings.

### BRIEF DESCRIPTION OF THE DRAWINGS

FIG. 1 is a schematic diagram of a conventional SRAM and the output device thereof.

FIG. 2 is a timing diagram of FIG. 1;

FIG. 3 is an equivalent schematic diagram of FIG. 1;

FIG. 4 is a detail circuit of an output device for SRAM in accordance with the invention; and

FIG. 5 is a timing diagram of FIG. 4.

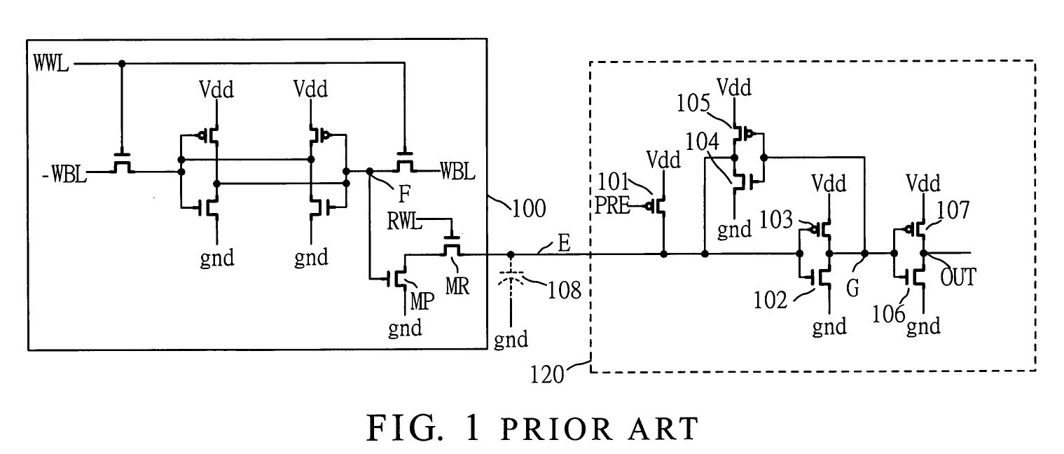

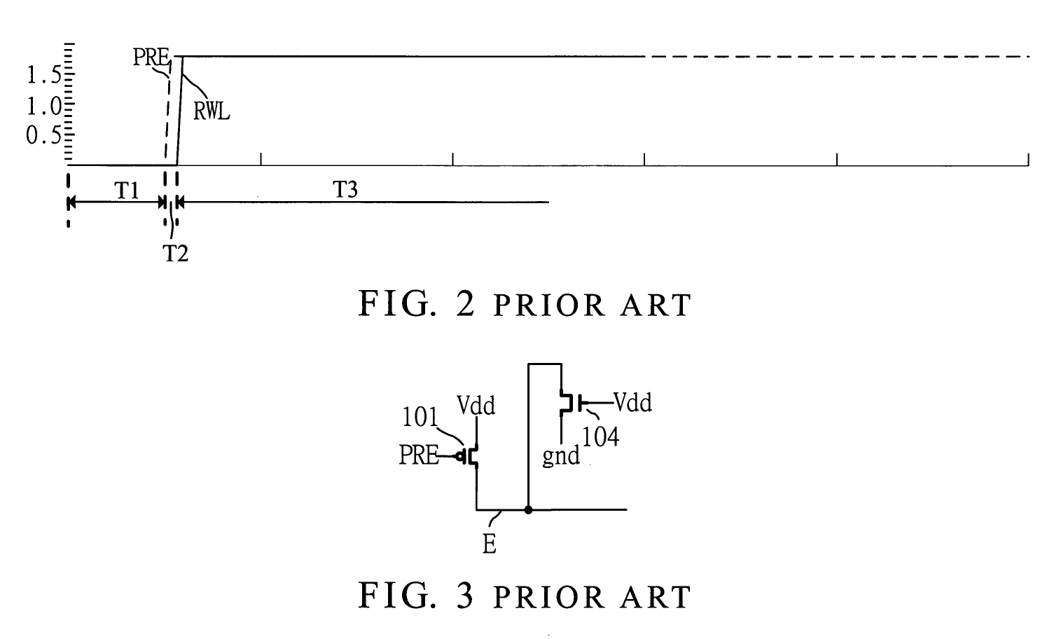

### DETAILED DESCRIPTION OF THE PREFERRED EMBODIMENT

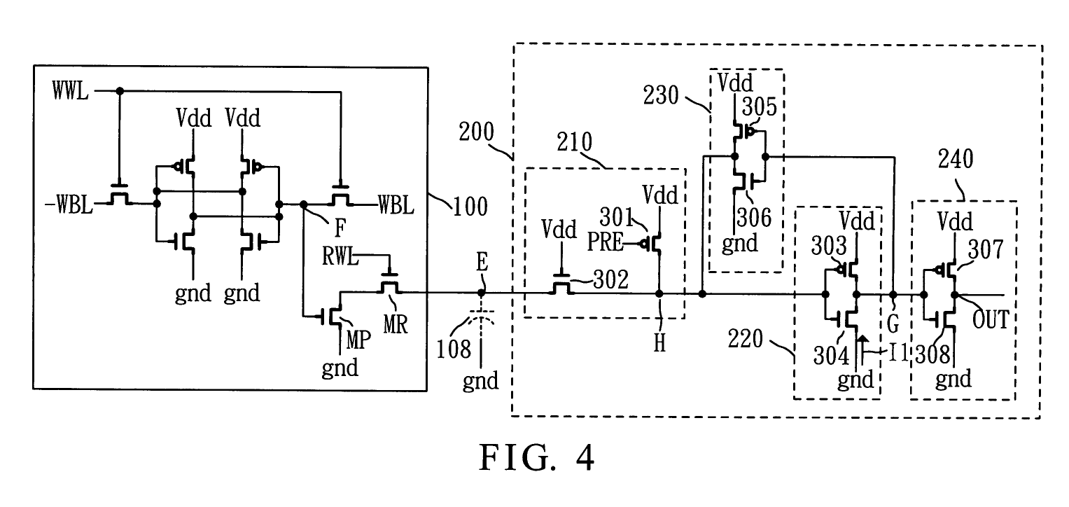

FIG. 4 shows a detail circuit of an output device for SRAM in accordance with a preferred embodiment of the invention, wherein multiple memory cells are connected to a common output node E, and only one memory cell 100 is shown for illustrative purpose. As shown, the output device 200 includes a precharger 210, a charge and discharge path circuit 220, a voltage hold circuit 230 and an output inverter 240.

The precharger 210 consists of a PMOS transistor 301 and an NMOS transistor 302. The PMOS transistor 301 has a gate connected to a precharge signal PRE, a source connected to a high potential Vdd, and a drain connected to a precharge node H. The NMOS transistor 302 acts as a transmitting gate coupled between the common output node E and the precharge node H and has a gate connected to a high potential Vdd.

Before reading the memory cell 100, the precharge signal PRE is changed to low potential to turn on the PMOS transistor 301. Next, the voltage Vdd precharges the node H through the source of the PMOS transistor 301 to a high voltage. Since the signal PRE is at low voltage, the node E is charged only to a voltage of (Vdd-V_{T}) because the gate of the NMOS transistor 302 is connected to the high potential Vdd when precharging to the node H.

The charge and discharge path circuit 220 consists of a PMOS transistor 303 and an NMOS transistor 304. The transistor 303 has a gate connected to the node H, a source connected to a high potential Vdd, and a drain connected to a drain of the transistor 304. The transistor 304 has a source connected to a ground voltage ‘gnd’ and a gate connected the node H.

The voltage hold circuit 230 consists of a PMOS 305 and an NMOS transistor 306. The transistor 305 has a gate connected to both the drain of the transistor 303 and the gate of the transistor 306, a source connected to a high voltage Vdd, and a drain connected to both the drain of the transistor 306 and the precharge node H. The transistor 306 has a source connected to the ground voltage ‘gnd’. The voltage of a path output node G of the charge and discharge path circuit 220 is used to control the NMOS transistor 306 to be turned on or off, thereby maintaining the potential on the node H.

The output inverter 240 consists of a PMOS transistor 307 and an NMOS transistor 308. The transistor 307 has a gate connected to both the path output node G and a gate of the transistor 308, a drain connected to both the OUT terminal and a drain of the transistor 308, and a source connected to a high potential. The transistor 308 has a source connected to a low potential. The output inverter 240 generates an inverse voltage to output in accordance with a voltage of the path output node G of the discharge path controller 230.

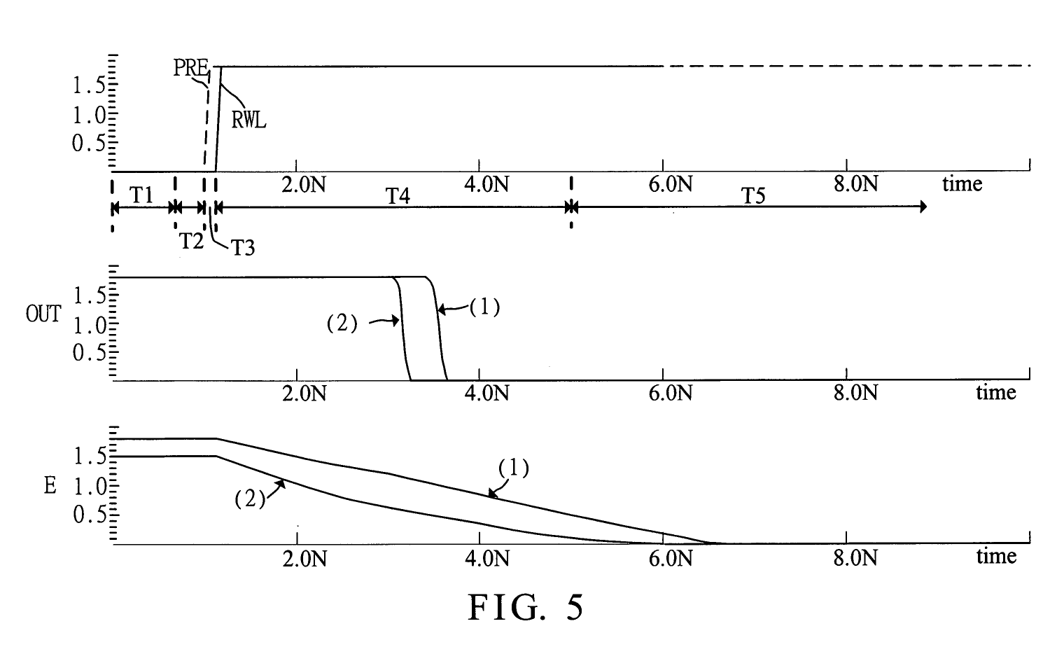

FIG. 5 is a read operation timing diagram of the output device 200 of FIG. 4 in accordance with the invention. As shown in FIG. 5, the output device 200 can be operable at an input voltage ranging between 0-1.8V, for example. First, in T1 interval, the output device 200 is pre-charged such that the signal PRE is at low potential to turn on the PMOS transistor 301. Next, the PMOS transistor 301 is turned on and its source voltage Vdd precharges the node H to a high potential (Vdd). Since the gate of the NMOS transistor 302 is connected to a high potential (Vdd), the node E can be charged only to a voltage of (Vdd-V_{T}).

Next, in T2 interval, the signal PRE is at high potential which indicates that precharging the node H to a high potential is complete. Next, in T3 interval, the memory cell 251 starts sending the data to the output device 200 when the control signal RWL changes from low to high and NMOS transistor MR is turned on.

If data stored in the memory cell 100 is a high potential (not shown), node F is at a low potential. As such, transistor MR is turned on and transistor MP is turned off. The node H is held at a precharged high potential (Vdd) to cause the transistor 303 to be in off state and the transistor 304 to be in on state, thereby providing a first grounding path I1 to hold the path output node G on low potential and outputting a high potential on the OUT terminal through the inverter 240.

On the contrary, if data stored in the memory cell 100 is a low potential, the node F is at high potential. As such, the transistors MR and MP are turned on to change the voltage of node E from (Vdd-V_{T}) to a low potential, and thus the transistor 303 is turned on to provide the node G with a high potential, thereby outputting a low potential from the OUT terminal. Also, the transistor 306 is turned on. Because time interval for changing the node E from (Vdd-V_{T}) to a low potential is shorter than that from Vdd to the low potential, curve illustrating voltage changes of the node E is shifted from notation (1) to (2) in FIG. 5. Also, it is shown that the switching time is much faster at notation (2) than at notation (1) in voltage changes of the OUT terminal.

In view of foregoing, it is known that in T1 interval, because the NMOS transistor 302 is provided in the precharger 210, the voltage of node E can be only charged to a potential of (Vdd-V_{T}). Therefore, in T3 interval, pulling down the potential of the node E to a certain low potential is quicker and thus speed of reading data out of the memory cell 100 is increased.

Although the present invention has been explained in relation to its preferred embodiment, it is to be understood that many other possible modifications and variations can be made without departing from the spirit and scope of the invention as hereinafter claimed.

1. An output device for static access memory (SRAM), the SRAM having a plurality of memory cells to store data, the output device comprising:
a precharger connected to a common output node for a plurality of memory cells, having a precharge node and at least one transmitting gate coupled between the common output node and the precharge node, precharging the precharge node to a high voltage when one of the memory cells is to be read;
a charge and discharge path circuit connected to the precharge node, controlling a path output voltage on a path output node of the charge and discharge path circuit in accordance with a voltage of the precharge node;
a voltage hold circuit connected to the path output node and the precharge node, controlling an output voltage of the voltage hold circuit in accordance with the path output voltage; and
an output inverter, generating an inverse voltage to output in accordance with the voltage of the path output node.

2. The output device as claimed in claim 1, wherein the transmitting gate is a first NMOS transistor to transmit a logic level of the common output node to the precharge node.

3. The output device as claimed in claim 2, wherein the first NMOS transistor has a gate connected to a high potential.

4. The output device as claimed in claim 1, wherein the precharge circuit further comprises a first PMOS transistor to turn on for precharging the precharge node to a high potential when one of the memory cells is to be read.

5. The output device as claimed in claim 1, wherein the charge and discharge path circuit is formed by connecting a second PMOS transistor and a second NMOS transistor in series such that the second NMOS transistor is turned on when the precharge node is at high potential and conversely the second PMOS transistor is turned on.

6. The output device as claimed in claim 1, wherein the voltage hold circuit is formed by connecting a third PMOS transistor and a third NMOS transistor in series such that the third NMOS transistor is turned on when the path output voltage is a high potential and conversely the third PMOS transistor is turned on.

7. The output device as claimed in claim 1, wherein the output inverter is formed by connecting a fourth PMOS transistor and a fourth NMOS transistor in series such that, in accordance with the voltage of the path output node, an inverse voltage is generated to output.
